(19) United States
(12) Patent Application Publication
(10) Pub. No.: US 2026/0291457 A1
(43) Pub. Date: Sep. 24, 2026

(54) REDUCING OUTPUT STAGE INSERTION LOSS IN A MULTI-STAGE DIFFERENTIAL POWER AMPLIFIER CIRCUIT

(71) Applicant: Qorvo US, Inc., Greensboro, NC (US)

(72) Inventors: Nadim Khlat, Ceret (FR); James M. Retz, Cedar Rapids, IA (US)

(21) Appl. No.: 19/535,291

(22) Filed: Feb. 10, 2026

Related U.S. Application Data
(60) Provisional application No. 63/767,660, filed on Mar. 6, 2025.

(51) Int. Cl. H03F 3/45; H03F 3/24

(52) U.S. Cl. CPC H03F 3/45475; H03F 3/245; H03F 2200/451

(57) ABSTRACT

Reducing output stage insertion loss in a multi-stage differential power amplifier circuit is disclosed. Herein, a first differential power amplifier is always active, and a second differential power amplifier is only activated as needed to collaboratively amplify a radio frequency (RF) signal. The output stage includes an output hybrid coupler, which includes a pair of input ports coupled respectively to the first and the second differential power amplifiers and an output port coupled to a load circuit. The output hybrid coupler is configured to modulate a load impedance seen by the first differential power amplifier when an instantaneous power level of the RF signal falls within a pair of power thresholds. Furthermore, the output hybrid coupler is also configured to lower the load impedance at the pair of input ports to help reduce insertion loss of the output hybrid coupler.

### RELATED APPLICATIONS

This application claims the benefit of U.S. provisional patent application Ser. No. 63/767,660, filed on Mar. 6, 2025, the disclosure of which is hereby incorporated herein by reference in its entirety.

### FIELD OF THE DISCLOSURE

The present disclosure is related to reducing output stage insertion loss in a multi-stage differential power amplifier circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by advanced wireless communication technologies such as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit, a power amplifier circuit, and a power management circuit. Specifically, the transceiver circuit modulates the transmission signal to an intended transmission frequency, the power amplifier circuit amplifies the transmission signal to the desired power level, and the power management circuit supplies an envelope tracking (ET) to the power amplifier circuit. Understandably, to achieve the best possible efficiency and performance, the power management circuit must adapt the ET voltage in accordance with a modulation bandwidth of the transmission signal.

### SUMMARY

Embodiments of the disclosure relate to reducing output stage insertion loss in a multi-stage differential power amplifier circuit. Herein, a first differential power amplifier is always active, and a second differential power amplifier is only activated as needed to collaboratively amplify a radio frequency (RF) signal. The output stage includes an output hybrid coupler, which includes a pair of input ports coupled respectively to the first and the second differential power amplifiers and an output port coupled to a load circuit. The output hybrid coupler is configured to modulate a load impedance seen by the first differential power amplifier when an instantaneous power level of the RF signal falls within a pair of power thresholds. Furthermore, the output hybrid coupler is also configured to lower the load impedance at the pair of input ports to help reduce insertion loss of the output hybrid coupler, especially when the output hybrid coupler is implemented in a process with high quality (high-Q) factors.

In one aspect, a multi-stage differential power amplifier circuit is provided. The multi-stage differential power amplifier circuit includes a driver stage circuit. The driver stage circuit is configured to amplify an RF signal and output a first differential signal and a second differential signal. The multi-stage differential power amplifier circuit also includes a first differential power amplifier. The first differential power amplifier is always active to amplify the first differential signal. The multi-stage differential power amplifier circuit also includes a second differential power amplifier. The second differential power amplifier is activated only when an instantaneous power level of the RF signal is higher than a first power threshold to amplify the second differential signal. The multi-stage differential power amplifier circuit also includes an output stage circuit. The output stage circuit includes an output hybrid coupler. The output hybrid coupler includes a quadrature input. The quadrature input is coupled to the first differential power amplifier. The output hybrid coupler also includes an in-phase input. The in-phase input is coupled to the second differential power amplifier. The output hybrid coupler also includes an isolation port. The isolation port is terminated by a termination impedance. The output hybrid coupler also includes an output port. The output port is coupled to a load circuit having a load resistance. The output hybrid coupler is configured to transform the load resistance to a lower resistance at each of the quadrature input and the in-phase input to thereby reduce an insertion loss caused by the output stage circuit. The output hybrid coupler is also configured to modulate a respective input impedance at each of the quadrature input and the in-phase input when the instantaneous power level of the RF signal is higher than the first power threshold but lower than or equal to a second power threshold.

In another aspect, a wireless device is provided. The wireless device includes a multi-stage differential power amplifier circuit. The multi-stage differential power amplifier circuit includes a driver stage circuit. The driver stage circuit is configured to amplify an RF signal and output a first differential signal and a second differential signal. The multi-stage differential power amplifier circuit also includes a first differential power amplifier. The first differential power amplifier is always active to amplify the first differential signal. The multi-stage differential power amplifier circuit also includes a second differential power amplifier. The second differential power amplifier is activated only when an instantaneous power level of the RF signal is higher than a first power threshold to amplify the second differential signal. The multi-stage differential power amplifier circuit also includes an output stage circuit. The output stage circuit includes an output hybrid coupler. The output hybrid coupler includes a quadrature input. The quadrature input is coupled to the first differential power amplifier. The output hybrid coupler also includes an in-phase input. The in-phase input is coupled to the second differential power amplifier. The output hybrid coupler also includes an isolation port. The isolation port is terminated by a termination impedance. The output hybrid coupler also includes an output port. The output port is coupled to a load circuit having a load resistance. The output hybrid coupler is configured to transform the load resistance to a lower resistance at each of the quadrature input and the in-phase input to thereby reduce an insertion loss caused by the output stage circuit. The output hybrid coupler is also configured to modulate a respective input impedance at each of the quadrature input and the in-phase input when the instantaneous power level of the RF signal is higher than the first power threshold but lower than or equal to a second power threshold.

In another aspect, a method for reducing output stage insertion loss in a multi-stage differential power amplifier circuit is provided. The method includes amplifying an RF signal and outputting a first differential signal and a second differential signal. The method also includes always activating a first differential power amplifier to amplify the first differential signal. The method also includes activating a second differential power amplifier only when an instantaneous power level of the RF signal is higher than a first power threshold to amplify the second differential signal. The method also includes transforming, using an output hybrid coupler, a load resistance coupled to an output port of the output hybrid coupler to a lower resistance at a quadrature input and an in-phase input to thereby reduce the output stage insertion loss. The method also includes modulating a respective input impedance at each of the quadrature input and the in-phase input when the instantaneous power level of the RF signal is higher than the first power threshold but lower than or equal to a second power threshold.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary power management circuit wherein a multi-stage differential power amplifier circuit is configured according to embodiments of the present disclosure to reduce insertion loss of an output stage circuit;

FIG. 2 is a graphic diagram illustrating an operating principle of the multi-phase differential power amplifier circuit in FIG. 1;

FIG. 3 is a schematic diagram providing an exemplary illustration of the output stage circuit in FIG. 1 configured to reduce insertion loss based on embodiments of the present disclosure;

FIG. 4 is a schematic diagram of an equivalent electrical model of the output stage circuit in FIG. 3 that helps to explain how the output stage circuit can reduce overall insertion loss according to embodiments of the present disclosure;

FIG. 5 is a schematic diagram of an exemplary communication device wherein the power management circuit of FIG. 1 can be provided; and

FIG. 6 is a flowchart of an exemplary process for reducing insertion loss of the output stage circuit in the multi-stage differential power amplifier circuit in FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to reducing output stage insertion loss in a multi-stage differential power amplifier circuit. Herein, a first differential power amplifier is always active, and a second differential power amplifier is only activated as needed to collaboratively amplify a radio frequency (RF) signal. The output stage includes an output hybrid coupler, which includes a pair of input ports coupled respectively to the first and the second differential power amplifiers and an output port coupled to a load circuit. The output hybrid coupler is configured to modulate a load impedance seen by the first differential power amplifier when an instantaneous power level of the RF signal falls within a pair of power thresholds. Furthermore, the output hybrid coupler is also configured to lower the load impedance at the pair of input ports to help reduce insertion loss of the output hybrid coupler, especially when the output hybrid coupler is implemented in a process with high quality (high-Q) factors.

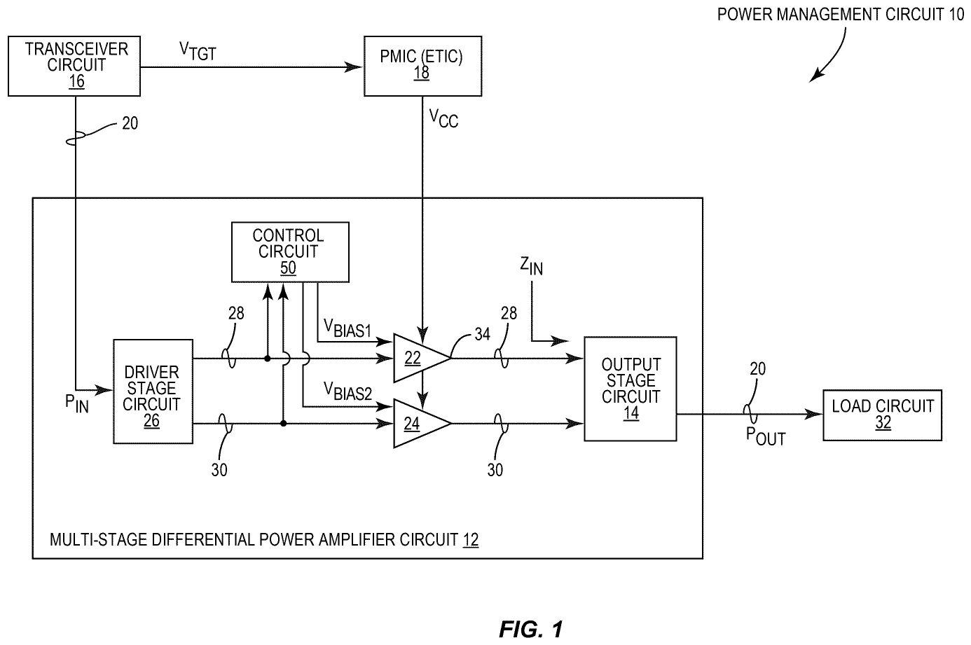

FIG. 1 is a schematic diagram of an exemplary power management circuit 10 wherein a multi-stage differential power amplifier circuit 12 is configured according to embodiments of the present disclosure to reduce insertion loss of an output stage circuit 14. In context of the present disclosure, a multi-stage differential power amplifier circuit refers generally to a power amplifier circuit that includes two or more amplification stages (e.g., driver stage and output stage). In addition, at least one of the amplification stages includes a differential power amplifier(s) configured to amplify a differential signal consisting of a pair of opposite-phased (e.g., a 0°-180° differential signal or a 90°-270° differential signal) signal components. Moreover, in the context of the present disclosure, a pair of signals (e.g., currents, voltages, or differential signals) can be said to be in a quadrature relationship when the pair of signals are ±90° out of phase (e.g., a 0°-180° differential signal vs. a 90°-270° differential signal) to each other.

Herein, the power management circuit 10 includes a transceiver circuit 16 and a power management integrated circuit (PMIC) 18. The transceiver circuit 16 is configured to generate an RF signal 20 having a time-variant input power P_{IN} and a target voltage V_{TGT} that tracks the time-variant input power P_{IN} of the RF signal 20. The PMIC 18 is configured to generate a supply voltage V_{CC} based on the target voltage V_{TGT}. In one embodiment, the PMIC 18 can generate the supply voltage V_{CC} as an envelope tracking (ET) voltage to track the time-variant input power P_{IN} of the RF signal 20. In this regard, the PMIC 18 will become an ET integrated circuit (ETIC).

In addition to the output stage circuit 14, the multi-stage differential power amplifier circuit 12 also includes a first differential power amplifier 22, a second differential power amplifier 24, and a driver stage circuit 26. The driver stage circuit 26 is configured to amplify the RF signal 20 and output a first differential signal 28 and a second differential signal 30 based on the amplified RF signal 20. The first differential power amplifier 22 is always active to further amplify the first differential signal 28 based on the supply voltage V_{CC}, whereas the second differential power amplifier 24 is only activated as needed to further amplify the second differential signal 30. The output stage circuit 14 is configured to serve dual purposes. On one hand, the output stage circuit 14 combines the amplified first differential signal 28 and the amplified second differential signal 30 (when available) to thereby output the amplified RF signal 20 to a coupled load circuit 32. On the other hand, the output stage circuit 14 is configured to manipulate a load impedance Z_{IN} at an output 34 of the first differential power amplifier 22 (a.k.a. “seen by the first differential power amplifier 22”) in accordance with the instantaneous power level of the RF signal 20.

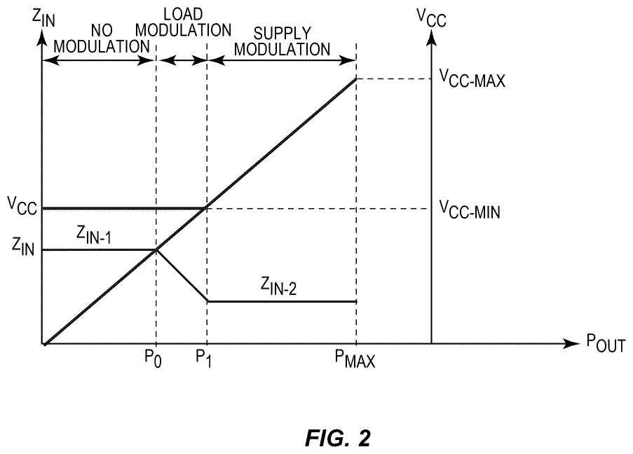

FIG. 2 is a graphic diagram illustrating an operating principle of the multi-stage differential power amplifier circuit 12 in FIG. 1. Common elements between FIGS. 1 and 2 are shown therein with common element numbers and will not be re-described herein.

In an embodiment, the output stage circuit 14 modulates the load impedance Z_{IN} based on a first power threshold P₀ and a second power threshold P₁. Herein, the second power threshold P₁ is approximately 8 to 10 dBs below a maximum power level P_{MAX} of the RF signal 20 and the first power threshold P₀ is approximately 4 to 6 dBs below the second power threshold P₁.

When the instantaneous power level of the RF signal 20 is lower than or equal to the first power threshold P₀, the output stage circuit 14 modulates the load impedance Z_{IN} at a first fixed level Z_{IN-1}. When the instantaneous power level of the RF signal 20 is higher than the second power threshold P₁, the output stage circuit 14 modulates the load impedance Z_{IN} at a second fixed level Z_{IN-2} (Z_{IN-2}<Z_{IN-1}). When the instantaneous power level of the RF signal 20 is higher than the first power threshold P₀ but lower than or equal to the second power threshold P₁, the output stage circuit 14 modulates the load impedance Z_{IN} in accordance with the instantaneous power level of the RF signal 20.

As illustrated herein, the output 34 of the first differential power amplifier 22 will see the highest value of the load impedance Z_{IN} (Z_{IN}=Z_{IN-1}) when the instantaneous power level of the RF signal 20 is lower than or equal to the first power threshold P₀. In other words, the output 34 of the first differential power amplifier 22 will see the highest value of the load impedance Z_{IN} (Z_{IN}=Z_{IN-1}) when the second differential power amplifier 24 is inactive. Thereafter, as the second differential power amplifier 24 is activated, the load impedance Z_{IN} will be reduced accordingly.

In addition to manipulating the load impedance Z_{IN} at the output 34 of the first differential power amplifier 22, the PMIC 18 is also configured to adapt the supply voltage V_{CC} in accordance with the instantaneous power level of the RF signal 20. Specifically, when the instantaneous power level of the RF signal 20 is lower than or equal to the first power threshold P₀, the PMIC 18 maintains the supply voltage V_{CC} constantly at a minimum voltage level V_{CC-MIN} independent of how the instantaneous power level of the RF signal 20 varies. Herein, the second differential power amplifier 24 is deactivated, whereas the first differential power amplifier 22 is activated to amplify the first differential signal 28 based on the supply voltage V_{CC}. As such, the multi-stage differential power amplifier circuit 12 is said to operate without modulation (a.k.a. “no modulation”).

When the instantaneous power level of the RF signal 20 is higher than the first power threshold P₀ but lower than or equal to the second power threshold P₁, the first differential power amplifier 22 will operate under full compression and the second differential power amplifier 24 will be activated. As such, the multi-stage differential power amplifier circuit 12 is said to operate based on load modulation. Herein, the PMIC 18 maintains the supply voltage V_{CC} at the minimum voltage level V_{CC-MIN}.

When the instantaneous power level of the RF signal 20 becomes higher than the second power threshold P₁, the second differential power amplifier 24 will also operate under full compression. The PMIC 18 will once again generate the supply voltage V_{CC} in accordance with the instantaneous power of the RF signal 20. In this regard, the multi-stage differential power amplifier circuit 12 will return to operating based on supply modulation. In the meantime, the first differential power amplifier 22 and the second differential power amplifier 24 will be biased equally to each deliver one-half (½) of the time-variant output power P_{OUT} and collectively drive the time-variant output power P_{OUT} toward the peak power level P_{MAX}.

With reference back to FIG. 1, the output stage circuit 14 can inherently cause an insertion loss in the RF signal 20. Generally speaking, insertion loss refers to an amount of power loss in the RF signal 20 when the RF signal 20 propagates through the output stage circuit 14. As such, the technical problem to be solved herein is how to reduce the insertion loss caused by the output stage circuit 14 in the multi-stage differential power amplifier circuit 12.

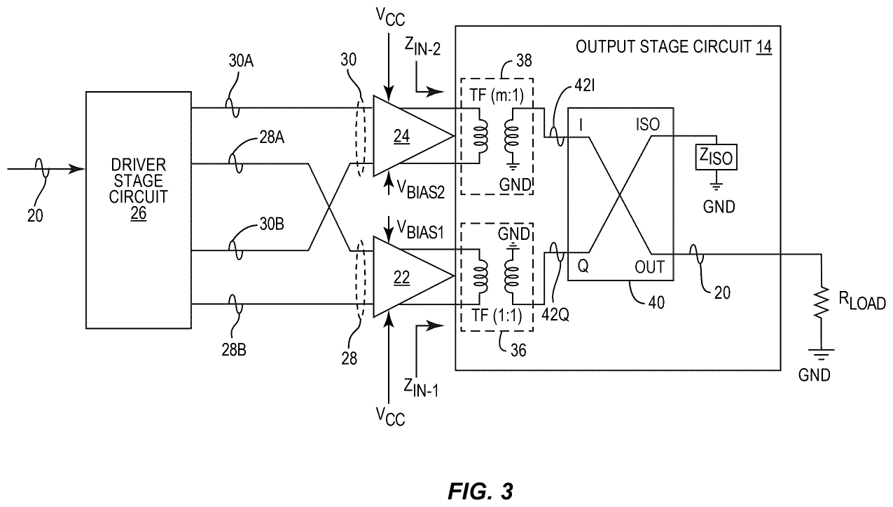

In this regard, FIG. 3 is a schematic diagram providing an exemplary illustration of the output stage circuit 14 in FIG. 1 configured to reduce insertion loss based on embodiments of the present disclosure. Common elements between FIGS. 1 and 3 are shown therein with common element numbers and will not be re-described herein.

Herein, the driver stage circuit 26 is configured to generate the first differential signal 28 and the second differential signal 30 from the RF signal 20. More specifically, the first differential signal 28 includes a first non-inverting component 28A and a first inverting component 28B, and the second differential signal 30 includes a second non-inverting component 30A and a second inverting component 30B. In a non-limiting example, first differential signal can be a 0°-180° differential signal whereas the second differential signal can be a 90°-270° differential signal.

The driver stage circuit 26 is coupled to the first differential power amplifier 22 and the second differential power amplifier 24. As discussed earlier in FIG. 2, the first differential power amplifier 22 is always activated to amplify the first differential signal 28, whereas the second differential power amplifier 24 is only activated as needed to amplify the second differential signal 30.

In an embodiment, the output stage circuit 14 includes a first transformer 36, a second transformer 38, and an output hybrid coupler 40. In this regard, the output stage circuit 14 includes no more than two transformers. The first transformer 36 is configured to convert the amplified first differential signal 28 into a quadrature output stage signal 42Q and the second transformer 38 is configured to convert the amplified second differential signal 30 into an in-phase output stage signal 42I.

The output hybrid coupler 40 includes a respective in-phase input (denoted as “I”), a respective quadrature input (denoted as “Q°), a respective isolation port (denoted as “ISO”), and a respective output port (denoted as “OUT”). In an embodiment, the isolation port (ISO) may be terminated by a termination impedance Z_{ISO}, and the output port (OUT) is coupled to the load circuit 32 as represented by a load resistance R_{LOAD}. The output hybrid coupler 40 receives the in-phase output stage signal 42I and the quadrature output stage signal 42Q via the in-phase input (I) and the quadrature input (Q), respectively. Accordingly, the output hybrid coupler 40 can combine the in-phase output stage signal 42I and the quadrature output stage signal 42Q to thereby output the amplified RF signal 20 via the output port (OUT). Herein, the first transformer 36, the second transformer 38, and the output hybrid coupler 40 can all be configured to reduce respective insertion loss according to embodiments described below.

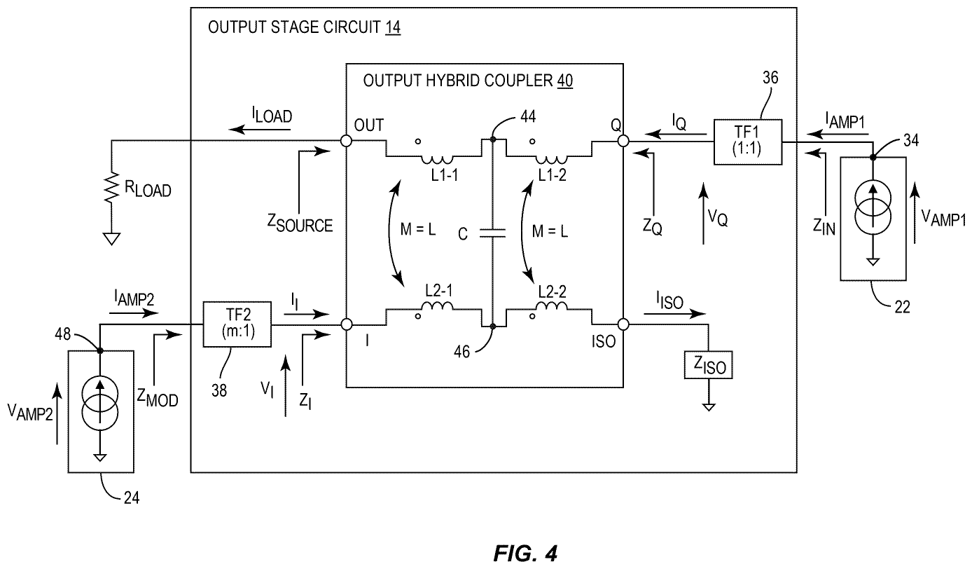

FIG. 4 is a schematic diagram of an equivalent electrical model of the output stage circuit 14 in FIG. 3 that helps to explain how the output stage circuit 14 can reduce overall insertion loss according to embodiments of the present disclosure. Common elements between FIGS. 3 and 4 are shown therein with common element numbers and will not be re-described herein.

By way of example, the output hybrid coupler 40 can be equated with a pair of first inductors L1-1, L1-2, a pair of second inductors L2-1, L2-2, and a capacitor C. Herein, each of the first inductors L1-1, L1-2 and the second inductors L2-1, L2-2 has an identical inductance L. The first inductors L1-1, L1-2 are coupled in series between the quadrature input (Q) and the output port (OUT). The second inductors L2-1, L2-2 are coupled in series between the in-phase input (I) and the isolation port (ISO). The first inductors L1-1, L1-2 and the second inductors L2-1, L2-2 are coupled by a mutual inductance M (M=L). The capacitor C is coupled between a first middle node 44 and a second middle node 46. As shown herein, the first middle node 44 is located in between the first inductors L1-1, L1-2 and the second middle node 46 is located in between the second inductors L2-1, L2-2.

According to an embodiment, the output hybrid coupler 40 is configured in accordance with the following equations (Eq. 1.1-1.5).

$$2 * M * s = + j * {R}_{LOAD} * β \qquad ( Eq . 1.1 )$$

$${Z}_{ISO} = - j * {R}_{LOAD} * β \qquad ( Eq . 1.2 )$$

$$1 / ( C * s ) = - j * 1 / ( {R}_{LOAD} * β ) \qquad ( Eq . 1.3 )$$

$${Z}_{IN} = {R}_{LOAD} * β \qquad ( Eq . 1.4 )$$

$${Z}_{MOD} = = {R}_{LOAD} * β \qquad ( Eq . 1.5 )$$

In the equations (Eq. 1.1-1.5), β represents a modification term that may not be changed dynamically. More specifically, β represents a desired ratio between the modulated impedance Z_{IN} at the output 34 of the first differential power amplifier 22 and a respective modulated load impedance Z_{MOD} at a respective output 48 of the second differential power amplifier 24 relative to the load resistance R_{LOAD}.

In FIG. 4, I_{Q}, V_{Q}, and Z_{Q} represent a respective current, a respective voltage, and a respective input impedance at the quadrature input (Q) of the output hybrid coupler 40. Similarly, I_{I}, V_{I}, and Z_{I} represent a respective current, a respective voltage, and a respective input impedance at the in-phase input (I) of the output hybrid coupler 40. Z_{SOURCE} represents a source impedance at the output port (OUT), I_{LOAD} represents a load current flowing through the output port (OUT), and R_{LOAD} represents the load resistance coupled to the output port (OUT). Z_{ISO} represents the termination impedance (e.g., capacitive or inductive impedance) that terminates the isolation port (ISO). In addition, I_{AMP1} and V_{AMP1} represent a respective current and a respective voltage of the first differential power amplifier 22, whereas I_{AMP2} and V_{AMP2} represent a respective current and a respective voltage of the second differential power amplifier 24.

The first transformer 36 is configured to transform the respective input impedance Z_{Q} at the quadrature input (Q) into the modulated load impedance Z_{IN} at the output 34 of the first differential power amplifier 22 based on a first transformation function (TF1). The second transformer 38, on the other hand, is configured to transform the input impedance Z_{I} at the in-phase input (I) into the modulated load impedance Z_{MOD} at the output 48 of the second differential power amplifier 24 based on a second transformation function (TF2).

According to an embodiment, the first transformation function (TF1) has a one-to-one (1:1) transformation ratio. As such, the first transformer 36 can perform the transformations as expressed in equations (Eq. 2.1-2.3) below.

$${Z}_{IN} = {Z}_{Q} \qquad ( Eq . 2.1 )$$

$${V}_{Q} = {V}_{AMP 1} \qquad ( Eq . 2.2 )$$

$${I}_{Q} = {I}_{AMP 1} \qquad ( Eq . 2.3 )$$

According to an embodiment, the second transformation function (TF2) has an m-to-one (m:1) transformation ratio. As such, the second transformer 38 can perform the transformations as expressed in equations (Eq. 3.1-3.3) below.

$${Z}_{MOD} = {Z}_{I} * {m}^{2} \qquad ( Eq . 3.1 )$$

$${V}_{I} = {V}_{AMP 2} / m \qquad ( Eq . 3.2 )$$

$${I}_{I} = {I}_{AMP 2} * m \qquad ( Eq . 3.3 )$$

In the equations (Eq. 3.1-3.3), m represents a transformation ratio. In this regard, it can be said that the second transformation function (TF2) is different from the first transformation function (TF1) by the transformation ratio (m). As further described below, the transformation ratio (m) can be determined to ensure that the modulated impedance Z_{IN} seen by the first differential power amplifier 22 is equal to the modulated impedance Z_{MOD} seen by the second differential power amplifier 24 (Z_{IN}=Z_{MOD}) when the instantaneous power level of the RF signal 20 is higher than the first power threshold P₀ but lower than or equal to the second power threshold P₁, whereas the currents I_{AMP1}, I_{AMP2} are equal in amplitude but quadrature in phase (e.g., I_{AMP2}=−j*I_{AMP1}).

The output stage circuit 14 as modeled in FIG. 4 will be obeyed by the following set of general equations.

$${Z}_{SOURCE} = 2 * M * s + 1 / ( C * s ) + {Z}_{ISO}$$

$${Z}_{IN} = {Z}_{lN [ 0 ]} + m * ( {I}_{AMP 2} / {I}_{AMP 1} ) * ( {R}_{LOAD} * {Z}_{ISO} - 2 * M / C ) / {Z}_{SOURCE} + {R}_{LOAD} )$$

$${Z}_{lN [ 0 ]} = ( {Z}_{ISO} + 1 / ( C * s ) ) * ( {R}_{LOAD} + 2 * M * s ) / {Z}_{SOURCE} + {R}_{LOAD} )$$

$${Z}_{MOD} = {Z}_{MOD [ 0 ]} + m * ( {I}_{AMP 1} / {I}_{AMP 2} ) * ( {R}_{LOAD} * {Z}_{ISO} - {2}^{⋆} M / C ) / ( {Z}_{SOURCE} + {R}_{LOAD} )$$

$${Z}_{MOD [ 0 ]} = ( {Z}_{ISO} + 2 * M * s ) * ( {R}_{LOAD} + 1 / ( C * s ) ) / ( {Z}_{SOURCE} + {R}_{LOAD} ) * {m}^{2}$$

$${I}_{LOAD} = {( {Z}_{ISO} + 1 / ( C * s ) )}^{⋆} {I}_{AMP 1} + ( {Z}_{ISO} + 2 * M * s ) * {I}_{AMP 2} * m / ( {Z}_{SOURCE} + {R}_{LOAD} )$$

In the above equations, the term m*(I_{AMP2}/I_{AMP1})*(R_{LOAD}*Z_{ISO}−2*M/C)/(Z_{SOURCE}+R_{LOAD}) allows the output hybrid coupler 40 to modulate the input impedance Z_{Q} at the quadrature input (Q), which will be transformed into the modulated load impedance Z_{IN} at the output 34 of the first differential power amplifier 22. On the other hand, Z_{IN[0]}represents the modulated impedance Z_{IN} at the output 34 of the first differential power amplifier 22 when the second differential power amplifier 24 is deactivated. In this regard, Z_{IN[0]}would be equivalent to the first fixed level Z_{IN-1} in FIG. 2, which is the highest modulated impedance seen at the output 34 of the first differential power amplifier 22.

As previously discussed in FIG. 2, the output stage circuit 14 is configured to perform load modulation at the output 34 of the first differential power amplifier 22 when the instantaneous power level of the RF signal 20 is higher than the first power threshold P₀ but lower than or equal to the second power threshold P₁. In this regard, to ensure that the modulated impedance Z_{IN} seen by the first differential power amplifier 22 is equal to the modulated impedance Z_{MOD} seen by the second differential power amplifier 24 (Z_{IN}=Z_{MOD}) when the currents I_{AMP1}, I_{AMP2} are equal in amplitude but quadrature in phase (e.g., I_{AMP2}=−j*I_{AMP}1), the transformation ratio (m) can be determined in accordance with equation (Eq. 4) below.

$$m = ( β + 1 / β ) / 2 \qquad ( Eq . 4 )$$

During the load modulation, when the currents I_{AMP1}, I_{AMP2} are equal in amplitude but quadrature in phase (e.g., I_{AMP2}=−j*I_{AMP}1) and when the isolation impedance Z_{ISO} is equal to −j*R_{LOAD}*β, the source impedance Z_{SOURCE}, the load current I_{LOAD}, the modulated impedance Z_{IN}, and the modulated load impedance Z_{MOD} can be described in equations (Eq. 5.1-5.4) below.

$${Z}_{SOURCE} = - j * {R}_{LOAD} / β \qquad ( Eq . 5.1 )$$

$${I}_{LOAD} = {I}_{AMP 1} + {I}_{AMP 2} * β \qquad ( Eq . 5.2 )$$

$${Z}_{IN} = {R}_{LOAD} * ( 1 + {β}^{2} ) / 2 \qquad ( Eq . 5.3 )$$

$${Z}_{MOD} = {R}_{LOAD} * ( 1 + {β}^{2} ) / 2 \qquad ( Eq . 5.4 )$$

As can be seen from the equation (Eq. 5.1), the source impedance Z_{SOUCE} will be different from the load resistance R_{LOAD} during load modulation.

As discussed in FIG. 2, the multi-stage differential power amplifier circuit 12 will operate based on supply modulation when the instantaneous power level of the RF signal 20 is higher than the second power threshold P₁. In this regard, the source impedance Z_{SOURCE} and the load current I_{LOAD} can be described in equations (Eq. 6.1 and 6.2) below when the isolation impedance Z_{ISO} is equal to R_{LOAD}*(1−j*β+j*1/β²).

$${Z}_{SOURCE} = {R}_{LOAD} \qquad ( Eq . 6.1 )$$

$${I}_{LOAD} = {I}_{AMP 1} * ( 3 + 1 / {β}^{2} ) / 4 * ( 1 - j * β ) \qquad ( Eq . 6.2 )$$

As can be seen from the equation (Eq. 6.1), the source impedance Z_{SOUCE} will be identical to the load resistance R_{LOAD} during supply modulation. As can be seen from the equation (Eq. 6.2), the load current I_{LOAD} during supply modulation has an extra gain compared to the load current I_{LOAD} during load modulation, especially when the modification term β is not equal to one.

The modulated impedance Z_{IN} during supply modulation at the output 34 of the first differential power amplifier 22 and the modulated impedance Z_{MOD} at the output 48 of the second differential power amplifier 24 can be determined based on equations (Eq. 7.1 and 7.2) below.

$${Z}_{IN} = {R}_{LOAD} * ( 2 + {β}^{2} + 1 / {β}^{2} ) / 4 \qquad ( Eq . 7.1 )$$

$${Z}_{MOD} = {R}_{LOAD} * ( 3 / 2 * {β}^{2} + 3 / 2 + 1 / ( 2 * {β}^{2} ) + 1 / ( 2 * {β}^{4} ) / 4 \qquad ( Eq . 7.2 )$$

As can be seen in the equations (Eq. 5.3 and 7.1), the modulated impedance Z_{IN} during supply modulation is also different from the modulated impedance Z_{IN} during load modulation. As such, it may not be appropriate to dynamically switch from load modulation to supply modulation. Nevertheless, it may be possible to switch between load modulation and supply modulation statically and use closed-loop power control to compensate for the extra gain in the load current I_{LOAD}. The static switching between load modulation and supply modulation may be used in a different modulation bandwidth and/or RF frequency.

According to an embodiment, it is possible to reduce insertion loss of the output stage circuit 14 in two aspects. In one aspect, the output hybrid coupler 40 can be configured to transform the load resistance R_{LOAD} to a lower resistance x*R_{LOAD} (x<1) at each of the quadrature input (Q) and the in-phase input (I) of the output hybrid coupler 40. In this regard, when the output hybrid coupler 40 is implemented in a lower loss process that has a higher quality factor (Q-factor), such as an integrated passive device (IPD) process, the insertion loss associated with the output hybrid coupler 40 can be reduced.

In another aspect, as a result of transforming the load resistance R_{LOAD} to the lower resistance x*R_{LOAD} (x<1), the first transformer 36 and/or the second transformer 38 can each perform a lesser amount of impedance transformations. This, in turn, makes it possible to reduce coil turns in the first transformer 36 and/or the second transformer 38 to thereby reduce insertion loss of the first transformer 36 and/or the second transformer 38. By reducing the insertion loss of the output hybrid coupler 40 and the insertion loss of the first transformer 36 and/or the second transformer 38, it is thus possible to reduce overall insertion loss of the output stage circuit 14.

With reference to FIG. 1, the multi-stage differential power amplifier circuit 12 can further include a control circuit 50. In an embodiment, the control circuit 50 may include a peak detector (not shown) configured to detect the instantaneous power level of the RF signal 20 based on the first differential signal 28 and the second differential signal 30. Accordingly, the control circuit 50 can selectively bias the first differential power amplifier 22 and the second differential power amplifier 24 based on a pair of bias voltages V_{BIAS1} and V_{BIAS2}, respectively. More specifically, the control circuit 50 may activate or deactivate the second differential power amplifier 24 by biasing or debiasing the second differential power amplifier 24 using the bias voltage V_{BIAS2}.

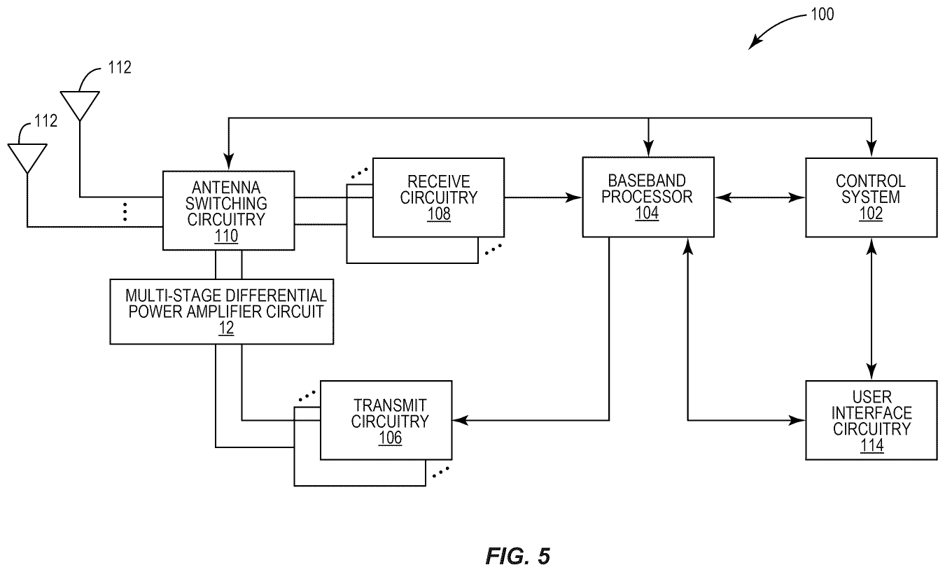

The power management circuit 10 of FIG. 1 can be provided in a communication device to support the embodiments described above. In this regard, FIG. 5 is a schematic diagram of an exemplary communication device 100 wherein the power management circuit 10 of FIG. 1 can be provided.

Herein, the communication device 100 can be any type of communication devices, such as mobile terminals, smart watches, tablets, computers, navigation devices, access points, base stations (e.g., eNB, gNB, etc.), and like wireless communication devices that support wireless communications, such as cellular, wireless local area network (WLAN), Ultra-wideband (UWB), Bluetooth, and near-field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor, an embedded memory circuit, and a communication bus interface. The receive circuitry 108 receives radio frequency signals via the antennas 112 and through the antenna switching circuitry 110 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application-specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 112 through the antenna switching circuitry 110. The multiple antennas 112 and the replicated transmit 106 and receive circuitry 108 may provide spatial diversity. Modulation and processing details will be understood by those skilled in the art.

In an embodiment, the transmit circuitry 106 and the receive circuitry 108 can function as the transceiver circuit 16 in FIG. 1. Accordingly, the multi-stage differential power amplifier circuit 12 can be provided between the transmit circuitry 106 and the antenna switching circuitry 110.

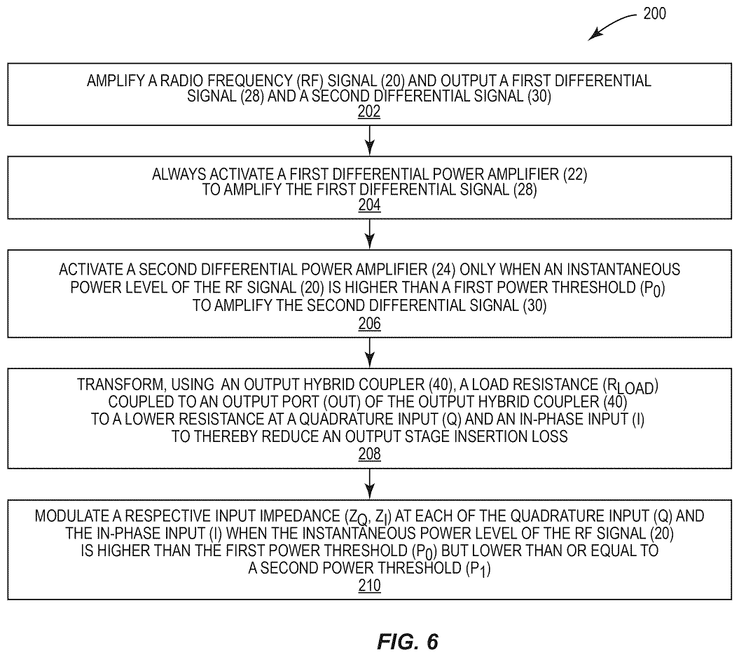

In an embodiment, it is possible to reduce insertion loss of the output stage circuit 14 in the power management circuit 10 of FIG. 1 in accordance with a process. In this regard, FIG. 6 is a flowchart of an exemplary process 200 for reducing insertion loss of the output stage circuit 14 in the multi-stage differential power amplifier circuit 12 in FIG. 1.

Herein, the process 200 includes amplifying the RF signal 20 and outputting the first differential signal 28 and the second differential signal 30 (step 202). The process 200 also includes always activating the first differential power amplifier 22 to amplify the first differential signal 28 (step 204). The process 200 also includes activating the second differential power amplifier 24 only when the instantaneous power level of the RF signal 20 is higher than the first power threshold P₀ to amplify the second differential signal 30 (step 206). The process 200 also includes transforming, using the output hybrid coupler 40, the load resistance R_{LOAD} coupled to the output port (OUT) of the output hybrid coupler 40 to the lower resistance at a quadrature input (Q) and an in-phase input (I) to thereby reduce the output stage insertion loss (step 208). The process 200 also includes modulating the respective input impedance Z_{Q}, Z_{I} at each of the quadrature input (Q) and the in-phase input (I) when the instantaneous power level of the RF signal 20 is higher than the first power threshold P₀ but lower than or equal to the second power threshold P₁ (step 210).

Those skilled in the art will recognize improvements and modifications to the preferred embodiments of the present disclosure. All such improvements and modifications are considered within the scope of the concepts disclosed herein and the claims that follow.

What is claimed is:

1. A multi-stage differential power amplifier circuit comprising:
a driver stage circuit configured to amplify a radio frequency (RF) signal and output a first differential signal and a second differential signal;
a first differential power amplifier that is always active to amplify the first differential signal;
a second differential power amplifier that is activated only when an instantaneous power level of the RF signal is higher than a first power threshold to amplify the second differential signal; and
an output stage circuit comprising an output hybrid coupler that comprises:
a quadrature input coupled to the first differential power amplifier;
an in-phase input coupled to the second differential power amplifier;
an isolation port terminated by a termination impedance; and
an output port coupled to a load circuit having a load resistance;
wherein the output hybrid coupler is configured to:
transform the load resistance to a lower resistance at each of the quadrature input and the in-phase input to thereby reduce an insertion loss caused by the output stage circuit; and
modulate a respective input impedance at each of the quadrature input and the in-phase input when the instantaneous power level of the RF signal is higher than the first power threshold but lower than or equal to a second power threshold.

2. The multi-stage differential power amplifier circuit of claim 1, wherein the output hybrid coupler is further configured to:
receive the amplified first differential signal via the quadrature input;
receive the amplified second differential signal via the in-phase input when the instantaneous power level of the RF signal is higher than the first power threshold; and
combine the amplified first differential signal and the amplified second differential signal to thereby output the amplified RF signal via the output port.

3. The multi-stage differential power amplifier circuit of claim 1, further comprising:
a first transformer coupled between a respective output of the first differential power amplifier and the quadrature input of the output hybrid coupler and configured to transform the respective input impedance at the quadrature input into a respective modulated load impedance at the respective output of the first differential power amplifier based on a first transformation function; and
a second transformer coupled between a respective output of the second differential power amplifier and the in-phase input of the output hybrid coupler and configured to transform the respective input impedance at the in-phase input into a respective modulated load impedance at the respective output of the second differential power amplifier based on a second transformation function.

4. The multi-stage differential power amplifier circuit of claim 3, wherein the second transformation function is different from the first transformation function by a transformation ratio so determined such that the respective modulated load impedance at the respective output of the first differential power amplifier is equal to the respective modulated load impedance at the respective output of the second differential power amplifier when respective currents in the first differential power amplifier and the second differential power amplifier are equal in amplitude but quadrature in phase.

5. The multi-stage differential power amplifier circuit of claim 4, wherein:
the output hybrid coupler is implemented based on an integrated passive device (IPD) process to thereby reduce the insertion loss of the output hybrid coupler; and
the first transformer and the second transformer are implemented in a laminate process to thereby reduce respective insertion losses of the first transformer and the second transformer.

6. The multi-stage differential power amplifier circuit of claim 1, wherein the output hybrid coupler is further configured to present a source impedance at the output port that is different from the load resistance when the instantaneous power level of the RF signal is higher than the first power threshold but lower than or equal to the second power threshold.

7. The multi-stage differential power amplifier circuit of claim 1, wherein the output hybrid coupler is further configured to present a source impedance at the output port that is identical to the load resistance when the instantaneous power level of the RF signal is higher than the second power threshold.

8. A wireless device comprising a multi-stage differential power amplifier circuit, the multi-stage differential power amplifier circuit comprises:
a driver stage circuit configured to amplify a radio frequency (RF) signal and output a first differential signal and a second differential signal;
a first differential power amplifier that is always active to amplify the first differential signal;
a second differential power amplifier that is activated only when an instantaneous power level of the RF signal is higher than a first power threshold to amplify the second differential signal; and
an output stage circuit comprising an output hybrid coupler that comprises:
a quadrature input coupled to the first differential power amplifier;
an in-phase input coupled to the second differential power amplifier;
an isolation port terminated by a termination impedance; and
an output port coupled to a load circuit having a load resistance;
wherein the output hybrid coupler is configured to:
transform the load resistance to a lower resistance at each of the quadrature input and the in-phase input to thereby reduce an insertion loss caused by the output stage circuit; and
modulate a respective input impedance at each of the quadrature input and the in-phase input when the instantaneous power level of the RF signal is higher than the first power threshold but lower than or equal to a second power threshold.

9. The wireless device of claim 8, wherein the output hybrid coupler is further configured to:
receive the amplified first differential signal via the quadrature input;
receive the amplified second differential signal via the in-phase input when the instantaneous power level of the RF signal is higher than the first power threshold; and
combine the amplified first differential signal and the amplified second differential signal to thereby output the amplified RF signal via the output port.

10. The wireless device of claim 8, wherein the multi-stage differential power amplifier circuit further comprises:
a first transformer coupled between a respective output of the first differential power amplifier and the quadrature input of the output hybrid coupler and configured to transform the respective input impedance at the quadrature input into a respective modulated load impedance at the respective output of the first differential power amplifier based on a first transformation function; and
a second transformer coupled between a respective output of the second differential power amplifier and the in-phase input of the output hybrid coupler and configured to transform the respective input impedance at the in-phase input into a respective modulated load impedance at the respective output of the second differential power amplifier based on a second transformation function.

11. The wireless device of claim 10, wherein the second transformation function is different from the first transformation function by a transformation ratio so determined such that the respective modulated load impedance at the respective output of the first differential power amplifier is equal to the respective modulated load impedance at the respective output of the second differential power amplifier when respective currents in the first differential power amplifier and the second differential power amplifier are equal in amplitude but quadrature in phase.

12. The wireless device of claim 10, wherein:
the output hybrid coupler is implemented based on an integrated passive device (IPD) process to thereby reduce the insertion loss of the output hybrid coupler; and
the first transformer and the second transformer are implemented in a laminate process to thereby reduce respective insertion losses of the first transformer and the second transformer.

13. The wireless device of claim 8, wherein the output hybrid coupler is further configured to present a source impedance at the output port that is different from the load resistance when the instantaneous power level of the RF signal is higher than the first power threshold but lower than or equal to the second power threshold.

14. The wireless device of claim 8, wherein the output hybrid coupler is further configured to present a source impedance at the output port that is identical to the load resistance when the instantaneous power level of the RF signal is higher than the second power threshold.

15. A method for reducing output stage insertion loss in a multi-stage differential power amplifier circuit comprising:
amplifying a radio frequency (RF) signal and outputting a first differential signal and a second differential signal;
always activating a first differential power amplifier to amplify the first differential signal;
activating a second differential power amplifier only when an instantaneous power level of the RF signal is higher than a first power threshold to amplify the second differential signal;
transforming, using an output hybrid coupler, a load resistance coupled to an output port of the output hybrid coupler to a lower resistance at a quadrature input and an in-phase input to thereby reduce the output stage insertion loss; and
modulating a respective input impedance at each of the quadrature input and the in-phase input when the instantaneous power level of the RF signal is higher than the first power threshold but lower than or equal to a second power threshold.

16. The method of claim 15, further comprising:
receiving the amplified first differential signal via the quadrature input;
receiving the amplified second differential signal via the in-phase input when the instantaneous power level of the RF signal is higher than the first power threshold; and
combining the amplified first differential signal and the amplified second differential signal to thereby output the amplified RF signal via the output port.

17. The method of claim 15, further comprising:
transforming, using a first transformer coupled between a respective output of the first differential power amplifier and the quadrature input of the output hybrid coupler, the respective input impedance at the quadrature input into a respective modulated load impedance at the respective output of the first differential power amplifier based on a first transformation function; and
transforming, using a second transformer coupled between a respective output of the second differential power amplifier and the in-phase input of the output hybrid coupler, the respective input impedance at the in-phase input into a respective modulated load impedance at the respective output of the second differential power amplifier based on a second transformation function.

18. The method of claim 17, wherein the second transformation function is different from the first transformation function by a transformation ratio so determined such that the respective modulated load impedance at the respective output of the first differential power amplifier is equal to the respective modulated load impedance at the respective output of the second differential power amplifier when respective currents in the first differential power amplifier and the second differential power amplifier are equal in amplitude but quadrature in phase.

19. The method of claim 15, further comprising presenting a source impedance at the output port that is different from the load resistance when the instantaneous power level of the RF signal is higher than the first power threshold but lower than or equal to the second power threshold.

20. The method of claim 15, further comprising presenting a source impedance at the output port that is identical to the load resistance when the instantaneous power level of the RF signal is higher than the second power threshold.
